(19) United States
(12) Patent Application Publication
(10) Pub. No.: US 2016/0284897 A1
(43) Pub. Date: Sep. 29, 2016

(54) BACK-CONTACT SOLAR CELL SET AND MANUFACTURING METHOD THEREOF

(71) Applicant: MOTECH INDUSTRIES INC., New Taipei City (TW)

(72) Inventors: Shu-Yen LIU, Tainan City (TW); Chih-Ming WEI, Tainan City (TW); Chia-Chih CHUANG, Tainan City (TW)

(21) Appl. No.: 15/074,811

(22) Filed: Mar. 18, 2016

(30) Foreign Application Priority Data
Mar. 23, 2015 (TW) 104109312

(51) Int. Cl. H01L 31/0224; H01L 31/18

(52) U.S. Cl. CPC H01L 31/022441; H01L 31/1868

(57) ABSTRACT

A back-contact solar cell set includes a semiconductor substrate and a contact set. A back-surface of the semiconductor substrate includes a first cell region, a second cell region and a first outer-isolation region which separates said two cell regions. The first outer-isolation region has a first basin region and a first highland region which is higher than the first basin region. The contact set includes a first connecting electrode which covers the first basin region. The first cell region and the second cell region are electrically connected through the first connecting electrode.

### CROSS REFERENCE TO RELATED APPLICATION

This application claims the priority benefit of Taiwan Patent Application Serial Number 104109312, filed on Mar. 23, 2015, the full disclosure of which is incorporated herein by reference.

### BACKGROUND

1. Field of the Disclosure

This disclosure generally relates to a back-contact solar cell set and a manufacturing method thereof and, more particularly, to a back-contact solar cell set having a single substrate formed with a plurality of solar cells and a manufacturing method thereof.

2. Description of the Related Art

FIG. 1(a) is a top view of a back surface of a known back-contact crystalline silicon solar cell in which a single solar cell is formed in a semiconductor substrate 91. A back surface of the semiconductor substrate 91 is divided as an emitter region 92e, a back surface field region 92s and an isolation region 93 which separates the emitter region 92e and the back surface field region 92s. An emitter electrode 94e and a back-surface field electrode 94s are respectively disposed on the emitter region 92e and the back surface field region 92s to output electricity.

Please refer to FIG. 1(b), it is a partial cross-sectional view taken along line W-W′ in FIG. 1(a). A light receiving surface 911 of a semiconductor substrate 91 includes an antireflection layer 96 and a front-surface field region 97. To maximize an effective incident light area of a solar cell, no metal electrode is set to cover on the light receiving surface 911. A back passivation layer 95 is disposed on a back surface 912 to decrease the carrier recombination rate. The emitter electrode 94e and the back-surface field electrode 94s connect to the emitter region 92e and the back surface field region 92s through different passivation layer openings 95i. To define the emitter region 92e and the back surface field region 92s, which are separated from each other, on a same surface (e.g. on the back surface 912), an isolation region 93 is disposed between these two regions. A height of the isolation region 93 is larger than the emitter region 92e and the back surface field region 92s in a vertical direction of the substrate.

Some known back-contact semiconductor solar cells are disposed with a plurality of separated p-type doping regions (e.g. emitter regions of the n-type substrate), and a plurality of separated n-type doping regions (e.g. back surface field regions of the n-type substrate). However, in the known back-contact solar cells, the p-type doping regions and the n-type doping regions are not connected via electrodes.

Although the efficiency of back-contact solar cells is higher than that of other kinds of solar cells having electrodes disposed on the light receiving surface, the manufacturing process thereof is more complicated than that of others such that the back-contact solar cells are not mainstream products in the current market. Therefore, it is desired that the efficiency of the back-contact solar cells can be improved continuously without increasing the complexity of manufacturing as possible.

### SUMMARY

Therefore, one object of the present disclosure is to provide a back-contact solar cell set that improves the photoelectric conversion efficiency by forming a plurality of solar cells electrically cascaded together in a single substrate, and decreases the risk of electrode disconnection by lowering a height of outer-isolation region between two adjacent cells.

Another object of the present disclosure is to provide a manufacturing method of a back-contact solar cell set. The manufacturing of the back-contact solar cell set is expected to be accomplished with the complexity and cost of manufacturing keep about the same.

Therefore, one embodiment of a back-contact solar cell set in the present disclosure includes a semiconductor substrate and an electrode set disposed on a back surface of the semiconductor substrate. The back surface includes a first cell region, a second cell region and an outer-isolation region which separates the first cell region and the second cell region. The first cell region includes a first emitter region, a first back surface field region and an inner-isolation region which separates the first emitter region and the first back surface field region. The second cell region includes a second emitter region, a second back surface field region and an inner-isolation region which separates the second emitter region and the second back surface field region. The electrode set includes a first connecting electrode, a first emitter electrode directly connected to the first emitter region, a first back field electrode directly connected to the first back surface field region, a second emitter electrode directly connected to the second emitter region, and a second back field electrode directly connected to the second back surface field region. Furthermore, the first emitter electrode and the second back field electrode are electrically connected with each other via the first connecting electrode, and the first connecting electrode covers on a first basin region of the first outer-isolation region, wherein the first basin region is lower than a first highland region of the first outer-isolation region in a vertical direction of the semiconductor substrate.

The present disclosure also provides a manufacturing method of a back-contact solar cell set. The manufacturing method includes: providing a semiconductor substrate, forming a first cell region, a second cell region, and an outer-isolation region between the first cell region and the second cell region on a back surface of the semiconductor substrate, and forming an electrode set on the back surface. The first cell region includes a first emitter region, a first back surface field region and an inner-isolation region which separates the first emitter region and the first back surface field region. The second cell region includes a second emitter region, a second back surface field region and a second inner-isolation region which separates the second emitter region and the second back surface field region. The electrode set includes a first connecting electrode, a first emitter electrode which directly connects to the first emitter region, a first back field electrode which directly connects to the first back surface field region, a second emitter electrode which directly connects to the second emitter region, and a second back field electrode which directly connects to the second back surface field region. The first emitter electrode and the second back field electrode are electrically connected with each other via the first connecting electrode, and the first connecting electrode covers on a first basin region of the first outer-isolation region, wherein the first basin region is lower than a first highland region of the first outer-isolation region in a vertical direction of the semiconductor substrate.

The present disclosure provides a back-contact solar cell set including a semiconductor substrate and an electrode set on a back surface of the semiconductor substrate. The back surface includes a first cell region, a second cell region and a first outer-isolation region which separates the first cell region and the second cell region. The first cell region includes a first emitter region, a first back surface field region and an inner-isolation region which separates the first emitter region and the first back surface field region. The second cell region includes a second emitter region, a second back surface field region and a second inner-isolation region which separates the second emitter region and the second back surface field region. The electrode set includes a first connecting electrode, a first emitter electrode directly connected to the first emitter region, a first back field electrode directly connected to the first back surface field region, a second emitter electrode directly connected to the second emitter region, and a second back field electrode directly connected to the second back surface field region. Furthermore, the first emitter electrode and the second back field electrode are electrically connected with each other via the first connecting electrode, and the first connecting electrode covers on a first basin region of the first outer-isolation region, wherein the first basin region is lower than the first inner-isolation region and the second inner-isolation region in a vertical direction of the semiconductor substrate.

The solar cell set in the present disclosure has several advantages. By forming a plurality of solar cells in a single semiconductor substrate, the present disclosure provide a way to reduce the I²R loss (I: current; R: resistance) and further improve the photoelectric conversion efficiency. The risk of electrode disconnection is also decreased by lowering a height of an outer-isolation region between two adjacent cells. In addition, the complexity of the manufacturing method provided by the present disclosure is similar to that of the conventional back-contact solar cell set such that an object of improving the efficiency without increasing the manufacturing complexity is realized.

### BRIEF DESCRIPTION OF THE DRAWINGS

Other objects, advantages, and novel features of the present disclosure will become more apparent from the following detailed description when taken in conjunction with the accompanying drawings.

FIG. 1(a) is a top view of a back surface of a known back-contact solar cell.

FIG. 1(b) is a schematic diagram of a partial cross-sectional view taken along line W-W′ of the back-contact solar cell in FIG. 1(a).

FIG. 2(a) is a top view from a back surface of a back-contact solar cell set of a first embodiment of the present disclosure.

FIG. 2(b) is a schematic diagram of a doping region on a back surface of a back-contact solar cell set of a first embodiment of the present disclosure.

FIG. 2(c) is a top view from a back surface of a back-contact solar cell set of a first embodiment of the present disclosure, more particularly, indicating an opening of a back passivation layer.

FIGS. 3(a)-3(c) are schematic diagrams of partial cross-sectional views of a back-contact solar cell set of a first embodiment of the present disclosure, respectively showing the cross-section along line X-X′, line Y-Y′ and line Z-Z′ in FIG. 2(a).

FIG. 4 is a top view from a back surface of a back-contact solar cell set of a second embodiment of the present disclosure.

FIG. 5 is a flow chart of a manufacturing method of a back-contact solar cell set of the present disclosure.

FIGS. 6 and 7 respectively show the changing of cross-sectional structures taken along line X-X′ and line Y-Y′ in FIG. 2(a) during manufacturing.

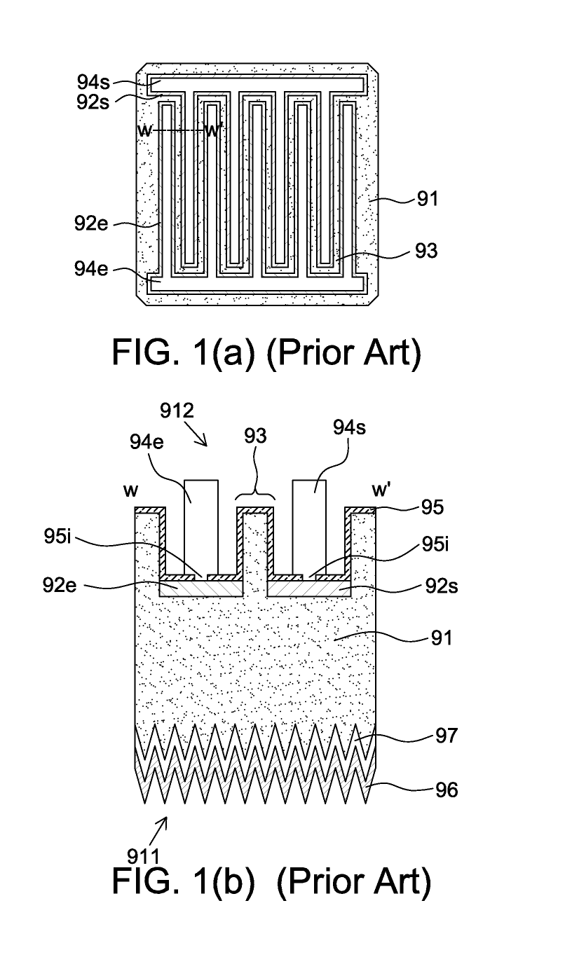

### DETAILED DESCRIPTION OF THE EMBODIMENT

It should be noted that, wherever possible, the same reference numbers will be used throughout the drawings to refer to the same or like parts.

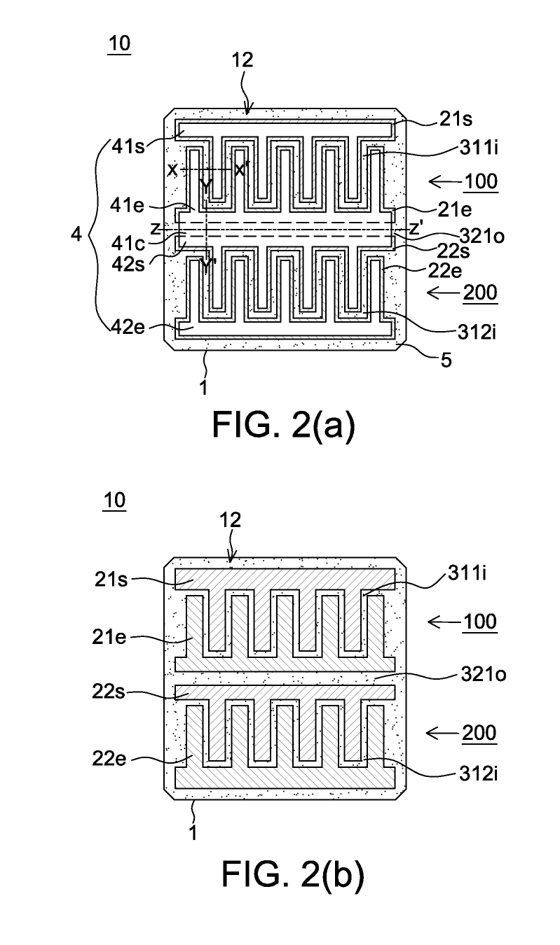

Referring to FIG. 2(a), it is a top view from a back surface of a back-contact solar cell set according to a first embodiment of the present disclosure. A back-contact solar cell set 10 includes a semiconductor substrate 1 whose material is, for example, the monocrystalline silicon or polysilicon. A back surface 12 of the semiconductor substrate 1 (as shown in FIG. 2(a)) includes a first cell region 100 and a second cell region 200, and the first cell region 100 and the second cell region 200 are separated by a first outer-isolation region 321o.

Referring to FIGS. 2(a) and 2(b), the first cell region 100 includes a first emitter region 21e, a first back surface field region 21s and a first inner-isolation region 311i which separates the first emitter region 21e and the first back surface field region 21s. The second cell region 200 includes a second emitter region 22e, a second back surface field region 22s and a second inner-isolation region 312i which separates the second emitter region 22e and the second back surface field region 22s.

The type of the emitter region (e.g. 21e, 22e) is contrary to that of a bulk region, while the type of the back surface field region (e.g. 21s, 22s) is the same as that of the bulk region. For example, if the bulk region is n-type, the emitter region is p-type, and the back surface field region is an n-type doping region whose concentration is higher than that of the bulk region. Furthermore, there is no intentional doping into said isolation regions (321o, 311i and 312i) so that the carrier type and carrier concentration thereof remain about the same as the original condition of the semiconductor substrate 1.

An electrode set 4 covers on the back surface 12 of the semiconductor substrate 1. The electrode set 4 includes a first emitter electrode 41e and a first back field electrode 41s which are respectively connected to the first emitter region 21e and the first back surface field region 21s, a second emitter electrode 42e and a second back field electrode 42s which are respectively connected to the second emitter region 22e and the second back surface field region 22s, and a first connecting electrode 41c which is connected to the first emitter electrode 41e and the second back field electrode 42s. The first connecting electrode 41c is used to electrically connect the first cell region 100 and the second cell region 200 in series.

In some embodiments, a back passivation layer 5 is formed between the electrode set 4 and the back surface 12. The material of the back passivation layer 5 is, for example, dielectric materials such as silicon nitride or silicon oxide for decreasing the carrier recombination rate. In this case, the opening is disposed at appropriate positions of the back passivation layer 5 such that each part (41e, 41s, 42e, 42s) of the electrode set 4 connects to the corresponded doping regions (21e, 21s, 22e, 22s) through said opening. Examples are described below.

It is seen from FIG. 2(b) that the first outer-isolation region 321o is located between the first emitter region 21e of the first cell region 100 and the second back surface field region 22s of the second cell region 200. Therefore, the first connecting electrode 41c crosses the first outer-isolation region 321o to connect to the first emitter electrode 41e and the second back field electrode 42s.

Furthermore, in this embodiment, other electrodes (41e, 41s, 42e, 42s) of the electrode set 4 do not cover on inner-isolation regions (311i, 312i) to effectively separate the different electrodes from one another and decrease the risk of short circuit.

FIG. 2(c) is a schematic diagram indicating the opening of the back passivation layer 5 in FIG. 2(a). The opening of the back passivation layer 5 includes a plurality of first inner-openings 51i located in the first cell region 100, a plurality of second inner-openings 52i located in the second cell region 200, and a first outer-opening 51o located in the first outer-isolation region 321o. The first emitter electrode 41e and the first back field electrode 41s respectively connect to the first emitter region 21e and the first back surface field region 21s through different first inner-openings 51i. The second emitter electrode 42e and the second back field electrode 42s respectively connect to the second emitter region 22e and the second back surface field region 22s through different second inner-openings 52i.

The first outer-opening 51o plays a role in lowering a height of the isolation region which is exposed by the same first outer-opening 51o (describe below). After the height of the exposed isolation region is lowered, a layer of appropriate dielectric material (e.g. silicon oxide or silicon nitride etc.) could be optionally added to cover the exposed isolation region to improve the passivation effect. In case the dielectric layer is added, the first outer-opening 51o is not appeared on the first outer-isolation region 321o of a final product of the cell set. In addition, each of the inner-isolation openings (311i, 312i) is completely covered by the back passivation layer 5 in this embodiment to ensure the passivation effect. In addition, while FIG. 2(c) shows that multiple first inner-openings 51i are disposed in a same doping region, it is not a necessity. It is also possible to dispose only one continuous back passivation opening in a single doping region (e.g. the first emitter region 21e). Similarly, it is also possible to dispose a plurality of first outer-openings in the first outer-isolation region 321o, and it is not necessarily to dispose the continuous back passivation opening 51o as shown in FIG. 2(c).

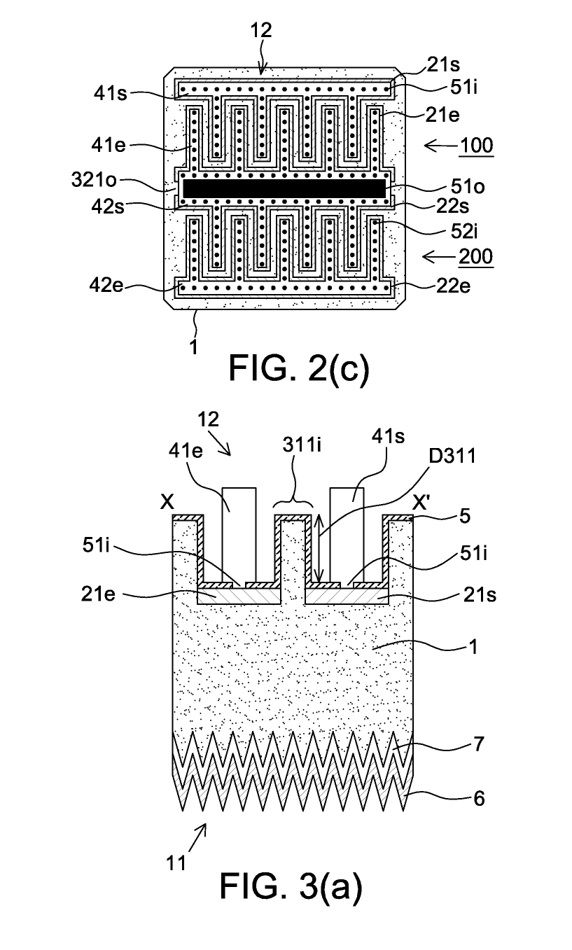

FIGS. 3(a), 3(b) and 3(c) are respectively schematic diagrams of a partial cross-sectional view taken along the line X-X′, line Y-Y′ and line Z-Z′ of the cell set of FIG. 2(a). FIGS. 3(a), 3(b) and 3(c) further represent a front-surface field region 7 being formed on a light receiving surface 11 of the semiconductor substrate 1 and covered by an antireflection layer 6.

Different types of the doping regions within the same cell region are separated by the inner-isolation region. For example, the first emitter region 21e and the first back surface field region 21s are separated by the first inner-isolation region 311i which is higher than the corresponded doping region as shown in FIG. 3(a). Electrodes connected to different types of the doping regions are also separated by the inner-isolation region which is higher than the corresponded doping region. For example, the first emitter region 41e and the first back surface field region 41s are separated by the first inner-isolation region 311i as shown in FIG. 3(a). The above arrangement helps in avoiding the occurrence of short circuiting and improving a yield rate of manufacturing process. For similar purpose, the second emitter region 22e (the second emitter electrode 42e) and second back-surface field 22s (the second back field electrode 42s) are also separated by the second inner-isolation region 312i which is higher than the corresponded doping region.

Different cell regions are separated by outer-isolation regions. For example, the first emitter region 21e (the first cell region 100) and the second back surface field region 22s (the second cell region 200) in FIG. 3(b) are separated by the first outer-isolation region 321o. In some embodiments, because the first connecting electrode 41c crosses the first outer-isolation region 321o, it is an option to lower a height of the first outer-isolation region 321o in a vertical direction of the substrate (referred as a height direction herein) to decrease the risk of the disconnection of the first connecting electrode.

To be more precisely, if a drop between the first outer-isolation region 321o and the doping region around the first outer-isolation region 321o (e.g. the first emitter region 21e or the second back surface field region 22s) in the height direction is defined as a first outer-drop D321 (as shown in FIG. 3(b)), a drop between the first inner-isolation region 311i and the doping region around the first inner-isolation region 311i (e.g. the first emitter region 21e or the first back surface field region 21s) in the height direction is defined as a first inner-drop D311, and a drop between the second inner-isolation region 312i and the doping region around the second inner-isolation region 312i (e.g. the second emitter region 22e or the second back surface field region 22s) in the height direction is defined as a second inner-drop D312, the first outer-drop D321 is smaller than the first inner-drop D311 and/or smaller than the second inner-drop D312.

According to the manufacturing method (said latter) of the present disclosure, for lowering a height of the first outer-isolation region 321o, a portion of the back passivation layer 5 is removed to form the first outer-opening 51o (i.e. the first outer-opening 51o located within the first outer-isolation region 321o). Therefore, in this embodiment, the outer-opening 51o is completely covered by the first connecting electrode 41c to prevent the substrate surface not covered by the back passivation layer 5 from outside contamination. Because the area of the first connecting electrode 41c is limited, it is able to accomplish the coverage of the first basin region 321t with the first connecting electrode 41c in a more economical way by only lowering a height of the first basin region 321t of the first outer-isolation region 321o without changing a height of a first highland region 321b beside the first basin region 321t which is still covered by the back passivation layer 5, as shown in FIG. 3(c). More specifically, when only the height of the first basin region 321t is lowered, the outer-drop D321 is referred to a drop between the first basin region 321t and the doping region around the first basin region 321t (e.g. the first emitter region 21e or the second back surface field region 22s) in the height direction.

In some embodiments, the first basin region 321t extends between the first cell region 100 and the second cell region 200 in a transverse direction (e.g. left and right direction in the figure), and the first highland region 321b locates at two sides of the first basin region 321t along the transverse direction, wherein the width of the first basin region 321t is larger than, equal to or smaller than the width of the doping regions of the first cell region 100 and the second cell region 200, but not limited to. In some embodiments, it is possible not to form the first basin region 321t continuously between the first cell region 100 and the second cell region 200, but the first highland region 321b is adjacent to the first basin region 321t. To be more precisely, the outer-isolation region 321o includes the first basin region 321t being partially etched and the first highland region 321b without being etched. Therefore, the first basin region 321t is lower than the first inner-isolation region 311i and the second inner-isolation region 321i in the vertical direction of the substrate surface.

According to the above arrangement, by forming two cells in a single substrate, it is able to reduce the length of the electrode and the doping region required by each cell, decrease the required thickness of the electrode an reduce the I²R loss (I: current; R: resistance) to improve the photoelectric conversion efficiency accordingly. Furthermore, the structure of the present disclosure could also be applied to the scheme that three or more than three solar cells are formed in a single substrate.

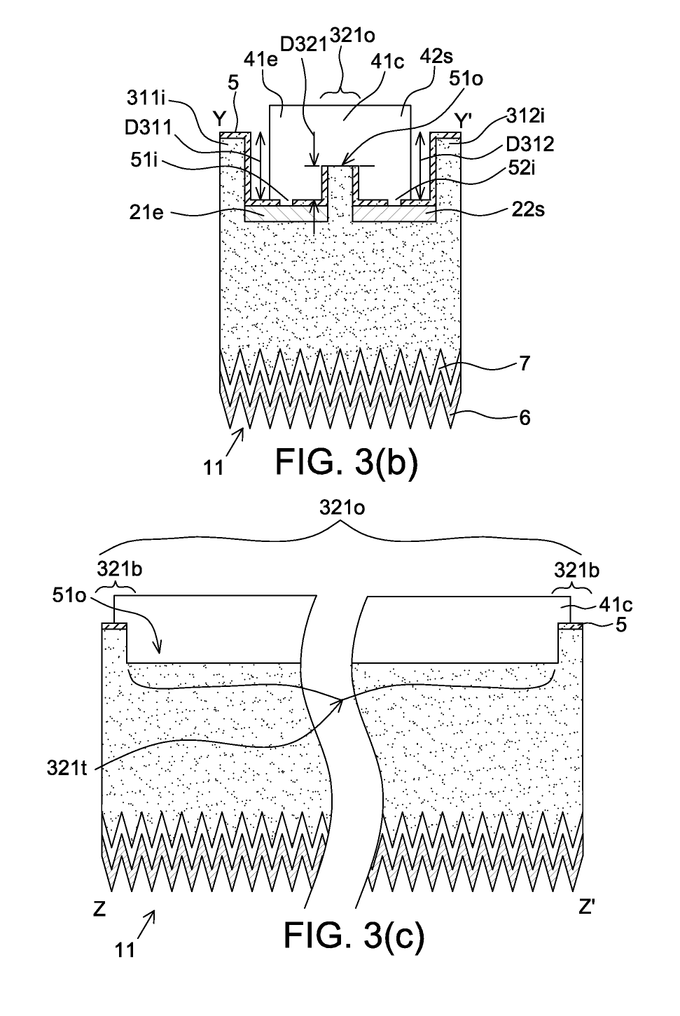

A second embodiment of a back-contact solar cell set in the present disclosure as shown in FIG. 4 is to form three solar cells in a single substrate. In this embodiment, in addition to a first cell region 100 and a second cell region 200, a third cell region 300 is further included. The second cell region 200 and the third cell region 300 are separated by a second outer-isolation region 322o. The third cell region 300 includes a third emitter region 23e, a third back surface field region 23s and a third inner-isolation region 313i which separates the third emitter region 23e and the third back surface field region 23s. The electrode set 4 further includes a third emitter electrode 43e and a third back field electrode 43s respectively connected to the third emitter region 23e and the third back surface field region 23s. In addition, the electrode set 4 also includes a second connecting electrode 42c crossing the second outer-isolation region 322o, and the second electrode 42c is electrically connected to the second emitter electrode 42e and the third back-surface electrode 43s to allow the second cell region 200 and the third cell region 300 to electrically cascade. All electrodes of the electrode set 4 are patterned electrodes formed by a same manufacturing process.

Additionally, similar to FIGS. 2(c) and 3(a)-3(c), the third emitter electrode 43e and the third back field electrode 43s of this embodiment respectively connect to the third emitter region 23e and the first back surface field region 23s via a plurality of third inner-openings (not shown) of the back passivation layer 5. The back passivation layer 5 also includes a second outer-opening (not shown) located in the second outer-isolation region 322o, and the second outer-isolation region 322o includes a second basin region and a second highland region. A shape and a location of the second basin region are corresponding to the second outer-opening, and a height of the second basin region is lower than that of the second highland region. The second connecting electrode 42c crosses the second outer-isolation region 322o via the second basin region to decrease the risk of disconnection. To be more precisely, the second basin region and the second highland region are possibly formed in a same manufacturing process with the first basin region and the first highland region.

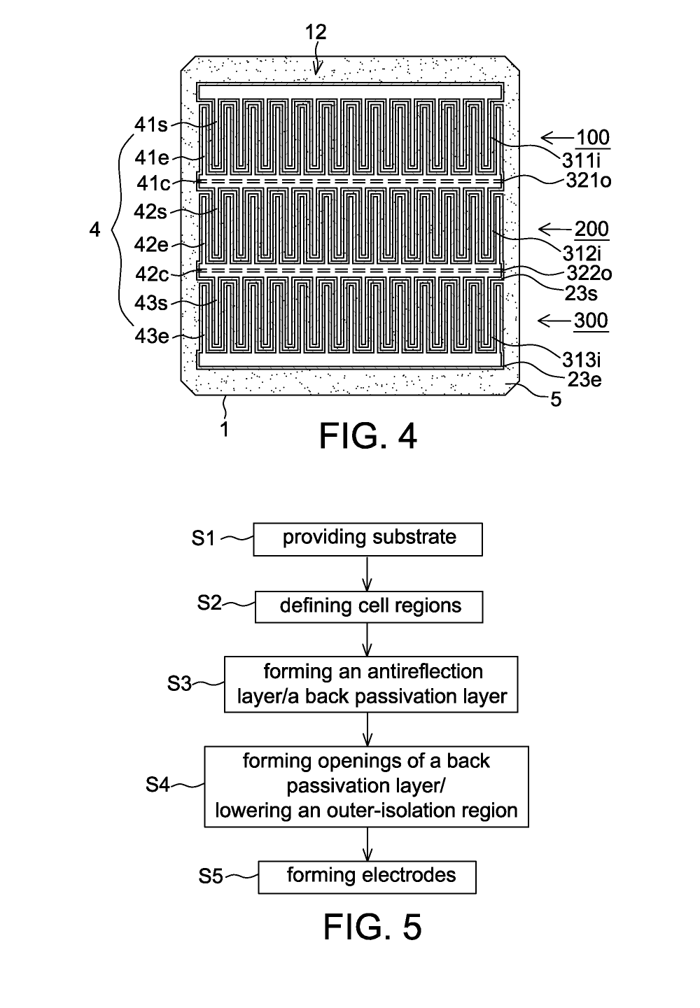

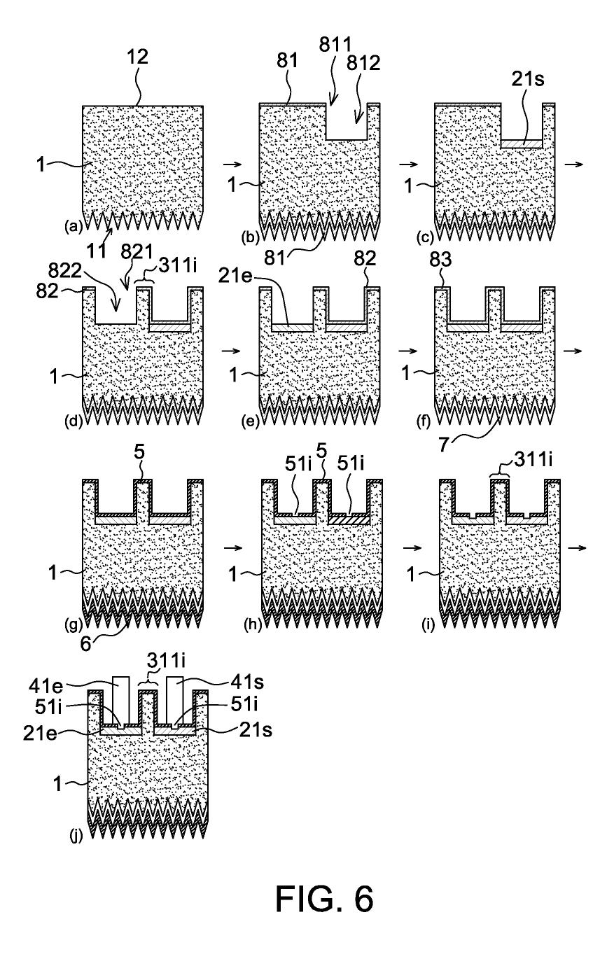

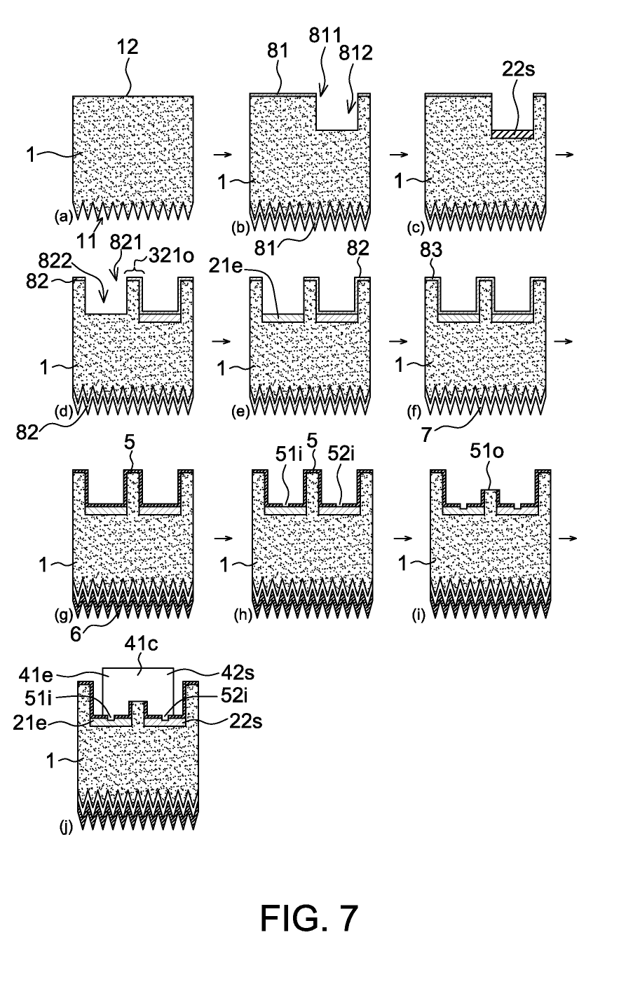

One embodiment of a manufacturing method of a back-contact solar cell set in the present disclosure for manufacturing a back-contact solar cell set of the present disclosure is illustrated below. For illustration purposes, said manufacturing process is illustrated by steps S1-S5 as shown in FIG. 5. FIGS. 6 and 7 respectively present the changing of the cross section of the first inner-isolation region 311i taken along line X-X′ and the first outer-isolation region 321o taken along line Y-Y′ as shown in FIG. 2(a) during manufacturing.

When the back-contact solar cell set includes more than two cell regions, the manufacturing of each inner-isolation region and each outer-isolation region is similar and thus details thereof are not described herein.

Step S1 performs the preparation of a substrate which includes the treatments such as texturing a light receiving surface 11 of a semiconductor substrate 1 and smoothing a back surface 12 of the semiconductor substrate 1. In this embodiment, the semiconductor substrate is illustrated by taking an n-type monocrystalline silicon substrate as an example. The surface of the semiconductor substrate 1 is etched by an appropriate concentration of mixed aqueous solution of potassium hydroxide (KOH) and isopropyl alcohol (IPA) to at least form pyramid-shaped texture on the light receiving surface 11. It is effective to decrease the reflectivity of the light receiving surface 11. For better adhering of the metal electrodes (i.e. electrode set 4), an appropriate concentration of potassium hydroxide (KOH) solution is applied to smooth the back surface 12. The structures after this step are shown in FIGS. 6(a) and 7(a).

Step S2 performs the definition of the cell region which includes defining a first cell region 100, a second cell region 200 and a first outer-isolation region 321o on the back surface 12 of the semiconductor substrate 1, and the first outer-isolation region 321o is between the first cell region 100 and the second cell region 200. This is described below with FIGS. 6(b)-6(f) and 7(b)-7(f).

Referring to FIGS. 6(b) and 7(b), a first doping barrier layer 81 of silicon oxide is formed on the back surface 12 of the semiconductor substrate 1, e.g. by a plasma-enhanced chemical vapor deposition (PECVD) method. Next, a part of the first doping barrier layer 81 is removed, for example, by a laser ablation to form a first barrier-layer opening 811. Then, the damaged part of the semiconductor substrate 1 during the laser ablation is removed by, for example, potassium hydroxide (KOH) solution so a first recessed region 812 is formed as shown in FIGS. 6(b) and 7(b).

Referring to FIGS. 6(c) and 7(c), an n-type doping region is formed in the first recessed region 812, e.g. by a thermal diffusion method or an ion implantation method, and the n-type doping region includes the first back surface field region 21s as shown in FIG. 6(c) and the second back surface field region 22s as shown in FIG. 7(c). As shown in FIGS. 6(c) and 7(c), if the doping is processed by the ion implantation method having a better directivity, the doping region mainly distributes at the bottom of the first recessed region 812. If the doping is processed by the thermal diffusion method having weak directivity, the doping region extends to the sidewall of the first recessed region 812.

Referring to FIGS. 6(d) and 7(d), which are similar to FIGS. 6(b) and 7(b), a second doping barrier layer 82 is formed on the back surface 12. Similarly, the second doping barrier layer 82 is formed, for example, by a plasma-enhanced chemical vapor deposition (PECVD) method. To simplify the manufacturing process, the second doping barrier layer 82 includes the residual first doping barrier layer 81 (e.g. not to remove the residual first doping barrier layer 81 after FIG. 7(c)), and then a second barrier-layer opening 821 is formed, for example, by laser ablation. The damaged part of the substrate is then removed by potassium hydroxide (KOH) solution to form a second recessed region 822. The first inner-isolation region 311i, the second inner-isolation 312i (referring to FIG. 2(a)) and the first outer-isolation region 321o are defined after this step.

Referring to FIGS. 6(e) and 7(e), a p-type doping region is formed in the second recessed region 822, for example, by a thermal diffusion method or an ion implantation method, and the p-type doping region includes a first emitter region 21e and a second emitter region 22e as shown in FIG. 2(a). Similarly, according to the directivity of the doping, said p-type doping region mainly distributes at the bottom or extends to the sidewall of the second recessed region 822. The first cell region 100, the emitter regions (21e, 22e) of the second cell region 200 and the back surface field regions (21s, 22s) are defined after this step.

FIGS. 6(f) and 7(f) show the process of forming the front-surface field region 7. That is, after the second doping barrier layer 82 is removed, the third doping barrier layer 83 is covered on a back surface 12 of the semiconductor substrate 1. The light receiving surface 11 is doped, for example, by n-type impurities such as phosphorus to form the front-surface field region 7, and then the third doping barrier layer 83 is removed.

It should be mentioned that although the present embodiment is illustrated by forming the back surface field regions, the emitter regions, and the front-surface region in sequence as an example, the sequence is changeable according to different requirements.

Step S3 is to form the antireflection layer 6 and the back passivation layer 5, as shown in FIGS. 6(g) and 7(g). The antireflection layer 6 is formed on the light receiving surface 11 with pyramid-shape texture. The antireflection layer 6 is, for example, silicon nitride based which improves the percentage of incident light entering the semiconductor substrate 1. The back passivation layer 5 locates on the back surface 12 and is, for example, silicon nitride based, silicon oxide based, aluminum oxide based or a multilayer combination thereof, which may lower the chance of carrier recombination to improve the photoelectric conversion efficiency.

Step S4 is to form openings of the back passivation layer 5 to lower the height of the outer-isolation region (e.g. 321o). Referring to FIGS. 3(b)-3(c), 6(h)-6(i) and 7(h)-7(i), the openings of the back passivation layer 5 are formed, for example, by laser ablation. The openings of the back passivation layer 5 include a plurality of the first inner-openings 51i located in the first cell region 100 and a plurality of the second inner-openings 52i located in the second cell region 200, and provide direct contact tunnels of the electrodes formed later to the cell emitter regions and the back surface field regions. In addition, the openings of the back passivation layer 5 further include the first outer-opening 51o located in the first outer-isolation region 321o. As mentioned above, after the laser ablation, the laser-damaged parts are removed, for example, by potassium hydroxide (KOH) solution. The manufacturing method in the present disclosure is to lower the height of the outer-isolation region 321o in the same time of removing the laser-damaged parts. That is, the exposed part of the substrate is etched through the first outer-opening 51o by potassium hydroxide (KOH) solution. Accordingly, the outer-isolation region 321o includes a lower first basin region 321t and a higher highland region 321b as shown in FIG. 3(c). Because the lowering process of the first outer-isolation region 321o is achieved in the same process of removing the laser-damaged parts as in the manufacturing process, the manufacturing complexity and the cost are substantially unchanged.

In addition, if a direct connection of the first basin region 321t to the electrode formed later is not desired, it is able to form an additional dielectric material (e.g. silicon nitride, silicon oxide or aluminum oxide based) to cover thereon. The additional dielectric material is formed after FIG. 7(i). By the way, as shown in FIGS. 6(h)-(i), the first inner-isolation region 311i and the other inner-isolations are still covered by the back passivation layer 5 during the laser ablation and the removing of the laser-damaged parts.

At last, the step S5 is to form patterned metal electrode to directly contact the doping region in the back surface. As shown in FIGS. 3(a)-3(b), 6(j) and 7(j), the first emitter electrode 41e and the first back field electrode 41s are respectively formed to directly connect to the first emitter region 21e and the first back surface field region 21s through different first inner-openings 51i, respectively. The second emitter electrode 42e and the second back field electrode 42s are formed to directly connect to the second emitter region 22e and the second back surface field region 22s via different second inner-openings 52i, respectively. Additionally, this step also includes forming a first connecting electrode 41c crossing the first outer-isolation region 321o, wherein the first connecting electrode 41c connects the first emitter electrode 41e and the second back field electrode 42s to allow the first cell region 100 and the second cell region 200 to be electrically connected. In some embodiments, the first connecting electrode 41c completely covers on the first basin region 321t to prevent the back surface exposition from being exposed due to not being covered by the back passivation layer 5. The first connecting electrode 41c completely or partially covers on the first highland region 321b without particular limitations as long as the region which is not covered by the passivation layer is covered thereby, wherein partially covering on the first highland region 321b saves the cost of material.

It should be mentioned that the scale and the spatial relationship between elements in the above embodiment are only intended to illustrate but not to limit the present disclosure.

As mentioned above, the present disclosure provides a structure of a back-contact solar cell set. The efficiency of the solar cell is improved by cascading several solar cells in a same semiconductor substrate, and the risk of electrode disconnection is decreased by lowering the height of an outer-isolation region between two adjacent cell regions. The present disclosure also provides a manufacturing method related to the back-contact solar cell set using an original etching process to lower the height of the outer-isolation region. By applying the structure of the present disclosure, it is able to achieve the object of the present disclosure without increasing the manufacturing complexity and cost.

Although the disclosure has been explained in relation to its preferred embodiment, it is not used to limit the disclosure. It is to be understood that many other possible modifications and variations can be made by those skilled in the art without departing from the spirit and scope of the disclosure as hereinafter claimed.

What is claimed is:

1. A back-contact solar cell set comprising:
a semiconductor substrate; and
an electrode set located on a back surface of the semiconductor substrate, wherein
the back surface comprises a first cell region, a second cell region and a first outer-isolation region which separates the first cell region and the second cell region,
the first cell region comprises a first emitter region, a first back surface field region and a first inner-isolation region which separates the first emitter region and the first back surface field region,
the second cell region comprises a second emitter region, a second back surface field region and a second inner-isolation region which separates the second emitter region and the second back surface field region,
the electrode set comprises a first connecting electrode, a first emitter electrode directly connected to the first emitter region, a first back field electrode directly connected to the first back surface field region, a second emitter electrode directly connected to the second emitter region, and a second back field electrode directly connected to the second back surface field region, and
the first emitter electrode electrically connects to the second back field electrode via the first connecting electrode, and the first connecting electrode covers on a first basin region of the first outer-isolation region, wherein the first basin region is lower than a first highland region of the first outer-isolation region in a vertical direction of the semiconductor substrate.

2. The back-contact solar cell set as claimed in claim 1, wherein a first outer-drop of the first basin region relative to doping regions around the first basin region is smaller than at least one of a first inner-drop of the first inner-isolation region relative to doping regions around the first inner-isolation region and a second inner-drop of the second inner-isolation region relative to doping regions around the second inner-isolation region.

3. The back-contact solar cell set as claimed in claim 2, further comprises a back passivation layer located on the back surface, wherein the back passivation layer completely covers on the first inner-isolation region and the second inner-isolation region, and the back passivation layer comprises at least one outer-opening located in the first basin region.

4. The back-contact solar cell set as claimed in claim 3, wherein the first connecting electrode directly contacts the first basin region via the first outer-opening.

5. The back-contact solar cell set as claimed in claim 3, wherein the back passivation layer locates between the back surface and the electrode set, and the back passivation layer further comprises a plurality of first inner-openings located in the first cell region and a plurality of second inner-openings located in the second cell region.

6. The back-contact solar cell set as claimed in claim 1, wherein the back surface further comprises:
a third cell region; and
a second outer-isolation region separating the second cell region and the third cell region, wherein
the third cell region comprises a third emitter region, a third back surface field region and a third inner-isolation region which separates the third emitter region and the third back surface field region, and
the electrode set further comprises a second connecting electrode, the second connecting electrode covered on a second basin region of the second outer-isolation region.

7. A manufacturing method of a back-contact solar cell set, the manufacturing method comprising:
providing a semiconductor substrate;
forming a first cell region, a second cell region, and a first outer-isolation region between the first cell region and the second cell region on a back surface of the semiconductor substrate; and
forming an electrode set on the back surface, wherein
the first cell region comprises a first emitter region, a first back surface field region and a first inner-isolation region which separates the first emitter region and the first back surface field region,
the second cell region comprises a second emitter region, a second back surface field region and a second inner-isolation region which separates the second emitter region and the second back surface field region,
the electrode set comprises a first connecting electrode, a first emitter electrode directly connected to the first emitter region, a first back field electrode directly connected to the first back surface field region, a second emitter electrode directly connected to the second emitter region, and a second back field electrode directly connected to the second back surface field region, and
the first emitter electrode electrically connects to the second back field electrode via the first connecting electrode, and the first connecting electrode covers on a first basin region of the first outer-isolation region, wherein the first basin region is lower than a first highland region of the first outer-isolation region in a vertical direction of the semiconductor substrate.

8. The manufacturing method as claimed in claim 7, further comprising:
performing an etching process before forming the electrode set to allow the first basin region to be lower than the first highland region.

9. The manufacturing method as claimed in claim 8, further comprising:
forming a back passivation layer on the back surface before the etching process, wherein
the back passivation layer comprises at least one first outer-opening for exposing at least the first basin region, and
the etching process etches the first basin region of the first outer-isolation region through the first outer-opening.

10. The manufacturing method as claimed in claim 9, wherein the back passivation layer further comprises:
a plurality of first inner-openings located in the first cell region; and
a plurality of second inner-openings located in the second cell region, wherein
the back passivation layer completely covers on the first inner-isolation region and the second inner-isolation region.

11. The manufacturing method as claimed in claim 10, wherein the first outer-opening, the first inner-openings and the second inner-openings are formed in a same process.

12. A back-contact solar cell set comprising:
a semiconductor substrate; and
an electrode set located on a back surface of the semiconductor substrate, wherein
the back surface comprises a first cell region, a second cell region and a first outer-isolation region which separates the first cell region and the second cell region,
the first cell region comprises a first emitter region, a first back surface field region and a first inner-isolation region which separates the first emitter region and the first back surface field region,
the second cell region comprises a second emitter region, a second back surface field region and a second inner-isolation region which separates the second emitter region and the second back surface field region,
the electrode set comprises a first connecting electrode, a first emitter electrode directly connected to the first emitter region, a first back field electrode directly connected to the first back surface field region, a second emitter electrode directly connected to the second emitter region, and a second back field electrode directly connected to the second back surface field region, and
the first emitter electrode electrically connects to the second back field electrode via the first connecting electrode, and the first connecting electrode covers on a first basin region of the first outer-isolation region, wherein the first basin region is lower than the first inner-isolation region and the second inner-isolation region in a vertical direction of the semiconductor substrate.
